(19) United States
(12) Patent Application Publication
(10) Pub. No.: US 2020/0406222 A1
(43) Pub. Date: Dec. 31, 2020

(54) REACTION CHAMBER COMPONENT, PREPARATION METHOD, AND REACTION CHAMBER

(71) Applicant: BEIJING NAURA MICROELECTRONICS EQUIPMENT CO., LTD., Beijing (CN)

(72) Inventors: Yicheng LI, Beijing (CN); Yulin PENG, Beijing (CN); Yongyou CAO, Beijing (CN)

(21) Appl. No.: 16/976,703

(22) PCT Filed: Dec. 3, 2018
(86) PCT No.: PCT/CN2018/118897

§ 371 Date: Aug. 28, 2020

(30) Foreign Application Priority Data
Mar. 8, 2018 (CN) 201810190001.5
Mar. 8, 2018 (CN) 201820317132.0

(51) Int. Cl. B01J 19/02; H01J 37/32; H01L 21/67; C25D 11/08; C25D 11/10

(52) U.S. Cl. CPC B01J 19/02; H01J 37/32495; H01J 37/32467; H01L 21/67069; H01J 2237/334; C25D 11/10; B01J 2219/029; B01J 2219/0218; C25D 11/08

(57) ABSTRACT

A reaction chamber component includes a body made of a 5000-series aluminum alloy material and an oxide film layer disposed on a surface-to-be-covered of the body.

### TECHNICAL FIELD

The disclosure belongs to the technical field of microelectronics processing, and in particular relates to a reaction chamber component, a preparation method, and a reaction chamber.

### BACKGROUND TECHNOLOGY

In the semiconductor manufacturing process, aluminum alloy is widely used to manufacture the reaction chamber component for the production of plasma. This is because not only the aluminum alloy has high strength and good weldability, but also the anode oxide film of aluminum alloy has good corrosion resistance. However, the aluminum alloy contains a large number of alloy elements, such as Mg, Cu, Zn, Mn, Fe, Si, etc. In the plasma etching process, the reacting gases used in the reaction chamber include CF₄/O₂, NF₃, Cl₂, CH₄/Ar, etc., and these reacting gases can generate a large number of active free radicals such as Cl and F and react with the alloy elements of the aluminum alloy to produce metal compound particles, which may easily cause metal contamination on the surface of the reaction chamber and severely affect the electrical performance of the device. In addition, the metal compound particles in the reaction chamber are difficult to clean, and long-term accumulation may cause the entire reaction chamber to fail.

At present, the base material of the reaction chamber component is usually made of 6000-series aluminum alloy such as A6061, and a layer of aluminum oxide film is formed on the surface of the component by the sulfuric acid anodic method, to prevent the reaction chamber component from being corroded by plasma. However, in practical applications, the reaction chamber components can still be easily corroded in the environment of plasma bombardment, which not only reduces the lifespan of the reaction chamber, but also causes metal contamination to the chamber.

### SUMMARY OF THE DISCLOSURE

The present disclosure aims to solve at least one of the technical problems existing in the existing technology, and proposes a reaction chamber component, a preparation method, and a reaction chamber, which can improve the corrosion resistance of the reaction chamber component, thereby improving the lifespan of the reaction chamber and reducing the metal contamination on the surface of the reaction chamber component.

In order to solve one of the above problems, the present disclosure provides a reaction chamber component, including: a body, and an oxide film layer disposed on a surface-to-be-covered of the body. The body is made of a 5000-series aluminum alloy material.

In some embodiments, the reaction chamber component further includes a ceramic layer covering a surface of the oxide film layer away from the surface-to-be-covered of the body.

In some embodiments, the surface of the oxide film layer away from the surface-to-be-covered of the body has a predetermined roughness for improving adhesion between the ceramic layer and the oxide film layer.

In some embodiments, the predetermined roughness has a value range of 3.2 μm to 6.3 μm.

In some embodiments, the ceramic layer includes yttrium oxide or zirconium oxide.

In some embodiments, a thickness of the ceramic layer ranges from 50 μm to 200 μm.

In some embodiments, the oxide film layer is made by oxidizing the surface-to-be-covered of the body.

In some embodiments, a thickness of the oxide film layer ranges from 50 μm to 60 μm.

As another technical solution, the present disclosure also provides a reaction chamber including the above-mentioned reaction chamber components provided by the present disclosure.

As another technical solution, the present disclosure also provides a method for preparing a reaction chamber component, including: producing the body with 5000-series aluminum alloy material; and covering the surface-to-be-covered of the body with an oxide film layer.

In some embodiments, during the process of covering the surface-to-be-covered of the body with the oxide film layer, an oxidation treatment may be performed on the surface-to-be-covered of the body of the to form the oxide film layer.

In some embodiments, performing oxidation treatment on the surface-to-be-covered of the body to form the oxide film layer includes: preheating the body; and placing the body in an electroplating tank containing nitric acid and oxalic acid for anodizing treatment to form the oxide film layer.

In some embodiments, a ratio of a mass percentage of nitric acid to a mass percentage of oxalic acid ranges from 0.8 to 1.2.

In some embodiments, the ratio can be 1.

In some embodiments, after the step of covering the surface-to-be-covered of the body with the oxide film layer, the method further includes: performing a sealing process to the oxide film layer.

In some embodiments, after forming the oxide film layer on the surface-to-be-covered of the body, the method further includes: covering the surface of the oxide film layer away from the surface-to-be-covered of the body with a ceramic layer.

In some embodiments, after forming the oxide film layer on the surface-to-be-covered of the body but before covering the surface of the oxide film layer away from the surface-to-be-covered of the body with the ceramic layer, the method further includes: performing a roughening process to the surface of the oxide film layer away from the surface-to-be-covered of the body to cause the surface to have the predetermined roughness that can improve the adhesion between the ceramic layer and the oxide film layer.

In some embodiments, performing a roughening process to the surface of the oxide film layer away from the surface-to-be-covered of the body to cause the surface to have the predetermined roughness that can improve the adhesion between the ceramic layer and the oxide film layer includes: sandblasting the surface of the oxide film layer away from the surface-to-be-covered of the body; and cleaning the surface of the oxide film layer away from the surface-to-be-covered of the body.

In some embodiments, covering the ceramic layer on the surface of the oxide film layer away from the surface-to-be-covered of the body includes: preheating the oxide film layer; selecting ceramic powder with a preset purity and a preset particle size, and spraying the ceramic power on the surface of the oxide film layer away from the surface-to-be-covered of the body to form the ceramic layer; and annealing the ceramic layer.

In some embodiments, the preset purity may be greater than 99.99%, and the value range of the preset particle size may be 5-10 μm.

The present disclosure has the following beneficial effects:

The present disclosure overcomes the technical prejudice in the existing technology that only considers the need for higher strength of the reaction chamber component and uses the 6000-series aluminum alloys. In the present disclosure, the 5000-series aluminum alloy is used to produce the body of the reaction chamber component. Since the 5000-series aluminum alloy is work-hardening Al-Mg aluminum alloy such as A5052, which contains very little Si element, it is not prone to grain boundary corrosion. Accordingly, the corrosion resistance of the reaction chamber component can be improved, thereby increasing the lifespan of the reaction chamber and reducing the metal contamination on the surface of the reaction chamber.

### BRIEF DESCRIPTION OF THE DRAWINGS

FIG. 1 is a schematic structural diagram of a reaction chamber component according to an embodiment of the present disclosure;

FIG. 2 is a flow chart of a method for preparing the reaction chamber component according to an embodiment of the present disclosure; and

FIG. 3 is another flow chart of the method for preparing the reaction chamber component according to an embodiment of the present disclosure.

### DETAILED DESCRIPTION OF THE EMBODIMENTS

In order to enable those skilled in the art to better understand the technical solutions of the present disclosure, the reaction chamber component, the preparation method, and the reaction chamber provided by the present disclosure will be described in detail below with reference to the accompanying drawings.

In this specification, the reaction chamber component may include, but is not limited to: an inner wall of the reaction chamber, a lining disposed on the inner wall, an adjustment bracket, and an electrostatic chuck.

FIG. 1 is a schematic structural diagram of a reaction chamber component. As shown in FIG. 1, an embodiment of the present disclosure provides a reaction chamber component, including: a body 1, and an oxide film layer 11 of a surface of body 1. The surface-to-be-covered of the body can be an entire outer surface-to-be-covered of the body 1, or it can also selectively cover a part of the outer surface-to-be-covered of the body 1. For example, the surface-to-be-covered of the body can be the surface-to-be-covered of the body 1 exposed in the reaction chamber.

The body 1 can be made of 5000 series aluminum alloy material.

Often, the 6000-series aluminum alloy is used to manufacture the body. The 6000-series aluminum alloy is a heat-treatable and strengthened Al-Mg-Si aluminum alloy (e.g., A6061). The aluminum alloy adds more Si elements to form a Mg₂Si reinforcing phase, thereby increasing the strength of the substrate. However, the excessive Si element can cause grain boundary corrosion, which affects the corrosion resistance of the reaction chamber components.

In this embodiment, the technical bias in the existing technology that only considers the need for higher strength of the reaction chamber components and uses the 6000-series aluminum alloys can be overcome. The 5000-series aluminum alloys are used to produce the body 1. Because the 5000-series aluminum alloys are work-hardened Al-Mg aluminum alloy (e.g., A5052, A5054, A5083, etc.) and contain very little Si element, they are not prone to grain boundary corrosion. Accordingly, the corrosion resistance of the reaction chamber component can be improved, thereby improving the lifespan of the reaction chamber and reducing the metal contamination on the surface of the reaction chamber component.

In this embodiment, the oxide film layer 11 is made by oxidizing the surface-to-be-covered of the body 1. The oxide film layer 11 has high roughness, and good corrosion resistance and wear resistance. In some embodiments, a thickness of the oxide film layer 11 ranges from 50 μm to 60 μm.

In this embodiment, the reaction chamber component further includes a ceramic layer 12 covering a surface of the oxide film layer 11 away from the surface-to-be-covered of the body. The ceramic layer 12 can be used as a barrier layer to prevent corrosion by plasma, so that the corrosion resistance of the reaction chamber components can be further improved.

In some embodiments, the surface of the oxide film layer 11 away from the surface-to-be-covered of the body has a predetermined roughness for improving adhesion between the ceramic layer 12 and the oxide film layer 11. Preferably, the predetermined roughness ranges from 3.2 μm to 6.3 μm, and within this range, the oxide film layer 11 and the ceramic layer 12 have strong adhesion.

It should be noted here that the above-mentioned predetermined roughness can be obtained by, but not limited to, plasma sandblasting.

In some embodiment, the above-mentioned ceramic layer 12 can be obtained by the following method: first, preheating the body 1 until the temperature of the body 1 reaches 100° C.-120° C.; then, selecting ceramic powder with a purity greater than 99.99% and a particle size range of 5 μm-10 μm, and spraying the ceramic powder on the surface of the oxide film layer 11 away from the surface-to-be-covered of the body to form the above-mentioned ceramic layer 12; after that, annealing the ceramic layer 12, preferably, but not limited to, annealing at a temperature of 100° C. to 120° C. for 2 to 5 hours. The ceramic layer 12 formed by this method can not only have higher purity and density, but also have a smaller porosity, which can better prevent the corrosion by plasma.

In some embodiments, the ceramic layer 12 includes but is not limited to: yttrium oxide or zirconium oxide. Since both yttrium oxide and zirconium oxide have better plasma corrosion resistance and longer lifespan than aluminum oxide, Compared with the barrier layer in the existing technology where only aluminum oxide is used as the barrier layer, the use of two barrier layers of the oxide film layer 11 and the ceramic layer 12 can greatly improve the corrosion resistance and lifespan of the reaction chamber component.

In addition, the thickness of the ceramic layer 12 ranges from 50 μm to 200 μm, which can well meet the requirements of corrosion resistance.

According to an embodiment of the present disclosure, there is further provided a reaction chamber, which includes the reaction chamber component provided in the foregoing embodiment of the present disclosure.

Specifically, the reaction chamber includes, but is not limited to: a physical vapor deposition chamber, a chemical vapor deposition chamber, an etching chamber.

The reaction chamber provided by the embodiment of the present disclosure can improve the corrosion resistance of the reaction chamber by using the reaction chamber component provided in the above embodiment, thereby increasing the lifespan of the reaction chamber and reducing the metal contamination on the surface of the reaction chamber component.

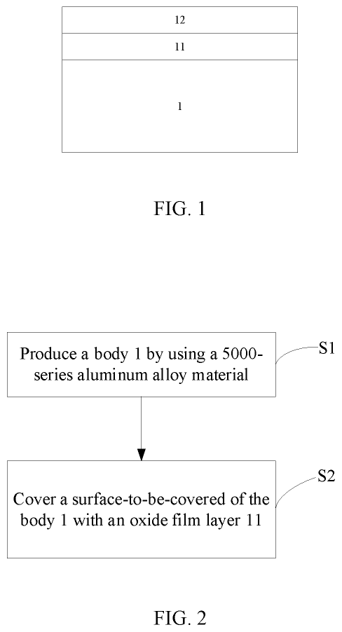

Referring to FIGS. 1 and 2, a method for preparing the reaction chamber component provided by the embodiment of the present disclosure includes the following:
S1: Producing a body 1 by using a 5000-series aluminum alloy material; and
S2: Covering a surface-to-be-covered of the body 1 with an oxide film layer 11.

Using the above preparation method provided in the embodiments of the present disclosure to prepare the reaction chamber component can improve the corrosion resistance of the reaction chamber component, thereby increasing the lifespan of the reaction chamber and reducing metal contamination on the surface of the reaction chamber component.

In the above step S2, the surface-to-be-covered of the body 1 may be oxidized to form an oxide film layer 11. The oxide film layer 11 may have high strength, and good corrosion resistance and wear resistance. In some embodiments, the thickness of the oxide film layer ranges from 50 μm to 60 μm.

In some embodiments, the foregoing S2, includes:
S21: Preheating the body 1; and
S22: Placing the body 1 in an electroplating tank containing nitric acid and oxalic acid to perform anodizing treatment to form the oxide film layer 11.

In the above step S21, preferably, the component body 1 can be placed in warm water of 30° C. to 40° C. for preheating. Specifically, a stirring method can be used to keep the solution in the electroplating tank at a uniform temperature, and the temperature can be set according to the actual processing temperature.

In the above step S22, the oxide film layer 11 can be formed by applying the mixed acid anodic oxidation method. Often, the 6000-series aluminum alloy contains more Si material. During the anodic oxidation process, silicon remains in the film as elemental particles, and may not be oxidized or dissolved. The mixed acid-based anodic oxidation requires high voltage. The silicon remained in the film can easily cause larger porosity of the oxide film, and when the film is thick, cracks are likely to form. In this embodiment, since the body 1 is made of the 5000-series aluminum alloy material, and the oxide film layer 11 is formed by the mixed acid anodic oxidation method, it can not only meet the requirements of strength, but also meet the requirements for the density of the oxide film layer 11.

Therefore, based on the method to produce the body 1 by using the 5000-series aluminum alloy material, the above step S22 is to use the mixed acid anodic oxidation method to form the oxide film layer 11, which can not only reduce the porosity of the oxide film layer 11, but also obtain the oxide film layer 11 with better temperature resistance to avoid the occurrence of cracks at high temperatures (e.g., 80° C.-120° C.), to be more suitable to meet the requirements of etching equipment above 14 nm. Of course, in practical applications, other oxidation methods can also be used to form the oxide film layer 11.

Preferably, a ratio of mass percentage of nitric acid to mass percentage of oxalic acid ranges from 0.8 to 1.2. More preferably, the ratio can be 1, which can further reduce the porosity of the oxide film layer 11.

In some embodiments, after the above step S2, the method further includes the following:
performing a sealing process to the oxide film layer 11. Specifically, the sealing process can adopt methods such as pressurized (for example, 110 kPa) steam sealing or boiling water sealing.

In practical applications, other mixed acids can also be used, for example, nitric acid and chromic acid, nitric acid and phosphoric acid, etc.

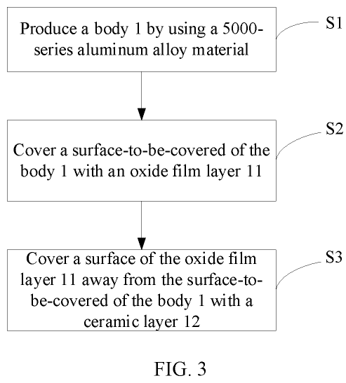

Referring to FIG. 3, preferably, after the above step S2, the method further includes:
S3: covering a surface of the oxide film layer 11 away from the surface-to-be-covered of the body with a ceramic layer 12.

The ceramic layer 12 can be used as a barrier layer to prevent the corrosion by plasma, so that the corrosion resistance of the reaction chamber component can be further improved.

In some embodiments, a thickness of the ceramic layer 12 ranges from 50 μm to 200 μm, and this range can well meet the corrosion resistance requirements.

In some embodiments, after step S2 and before step S3, the method further includes:
In step S23, the surface of the oxide film layer 11 away from the surface-to-be-covered of the body may be roughened, so that the surface can have a predetermined roughness for improving adhesion between the ceramic layer 12 and the oxide film layer 11.

Further, the value range of the aforementioned predetermined roughness may be 3.2 μm to 6.3 μm, and within this range, the adhesion between the oxide film layer 11 and the ceramic layer 12 can be strong.

In addition, preferably, the above step S23 includes:
S231: Sandblasting the surface of the oxide film layer 11 away from the surface-to-be-covered of the body; and
S232: Cleaning the surface of the oxide film layer 11 away from the surface-to-be-covered of the body.

In the above step S231, the method of sandblasting can be, but not limited to, the method of plasma sandblasting.

In this embodiment, the above step S3 includes:
S31: Preheating the oxide film layer 11;
S32: Selecting ceramic powder with a preset purity and a preset particle size, and spraying the ceramic power to the surface of the oxide film layer 11 away from the surface-to-be-covered of the body to form the ceramic layer 12; and
S33: Annealing the ceramic layer.

In the above step S31, the body 1 may be preheated until the temperature of the body 1 reaches 100° C. to 120° C.

In the above step S32, in some embodiments, the preset purity can be greater than 99.99%, and the value range of the preset particle size can be 5 μm-10 μm.

In the above step S33, it is preferable but not limited to annealing at a temperature of 100° C. to 120° C. for 2 to 5 hours.

The ceramic layer 12 formed by this method can not only have a higher purity and density, but also have a smaller porosity, which can better prevent the corrosion by plasma.

In some embodiments, the ceramic layer 12 includes yttrium oxide or zirconium oxide. Since both yttrium oxide and zirconium oxide have better plasma corrosion resistance and longer lifespan than aluminum oxide, compared with the existing technology where only aluminum oxide is used as the barrier layer, the use of the two barrier layers of oxide film layer 11 and ceramic layer 12 can largely improve the corrosion resistance and lifespan of the reaction chamber component.

It can be understood that the above implementations are merely exemplary implementations used to illustrate the principle of the present disclosure, but the present disclosure is not limited thereto. For those of ordinary skill in the art, various modifications and improvements can be made without departing from the spirit and essence of the present disclosure, and these modifications and improvements are also regarded as the scope of the disclosure.

1. A reaction chamber component, comprising:
a body made of a 5000-series aluminum alloy material, and
an oxide film layer disposed on a surface-to-be-covered of the body.

2. The reaction chamber component according to claim 1, further comprising:
a ceramic layer covering a surface of the oxide film layer away from the surface-to-be-covered of the body.

3. The reaction chamber component according to claim 2, wherein:
the surface of the oxide film layer away from the surface-to-be-covered of the body has a predetermined roughness for improving adhesion between the ceramic layer and the oxide film layer.

4. The reaction chamber component according to claim 3, wherein the predetermined roughness has a value range of 3.2 μm to 6.3 μm.

5. The reaction chamber component according to claim 2, wherein the ceramic layer comprises yttrium oxide or zirconium oxide.

6. The reaction chamber component according to claim 2, wherein a thickness of the ceramic layer ranges from 50 μm to 200 μm.

7. The reaction chamber component according to claim 1, wherein the oxide film layer is made by oxidizing the surface-to-be-covered of the body.

8. The reaction chamber component of claim 1, wherein a thickness of the oxide film layer ranges from 50 ∥m to 60 μm.

9. A reaction chamber, comprising: a reaction chamber component comprising:
a body made of a 5000-series aluminum alloy material; and
an oxide film layer disposed on a surface-to-be-covered of the body.

10. A method for preparing reaction chamber component, comprising:
producing a body by using a 5000-series aluminum alloy material; and
covering a surface-to-be-covered of the body with an oxide film layer.

11. The method for preparing reaction chamber component according to claim 10, wherein: covering the surface-to-be-covered of the body with the oxide film layer comprises:
performing oxidation treatment to the surface to form the oxide film layer.

12. The method for preparing reaction chamber component according to claim 11, wherein performing oxidation treatment on the surface-to-be-covered of the body to form the oxide film layer comprises:
preheating the component body; and
placing the body in an electroplating tank containing nitric acid and oxalic acid for anodic oxidation treatment to form the oxide film layer.

13. The method for preparing reaction chamber component according to claim 12, wherein a ratio of mass percentage of nitric acid to mass percentage of oxalic acid ranges from 0.8 to 1.2.

14. The method for preparing reaction chamber component according to claim 13, wherein the ratio is 1.

15. The method for preparing reaction chamber component according to claim 10, further comprising:
performing a sealing process to the oxide film layer.

16. The method for preparing reaction chamber component according to claim 10, further comprising:
after covering the surface-to-be-covered of the body with the oxide film layer:
covering a surface of the oxide film layer away from the surface-to-be-covered of the body with a ceramic layer.

17. The method for preparing reaction chamber component according to claim 16, further comprising:
after covering the surface-to-be-covered of the body with the oxide film layer and before covering the surface of the oxide film layer away from the surface-to-be-covered of the body with the ceramic layer:
roughening the surface of the oxide film layer away from the surface-to-be-covered of the body to cause the surface to have a predetermined roughness that can improve adhesion between the ceramic layer and the oxide film layer.

18. The method for preparing reaction chamber component according to claim 17, wherein roughening the surface of the oxide film layer away from the surface-to-be-covered of the body to cause the surface to have a predetermined roughness that can improve adhesion between the ceramic layer and the oxide film layer comprises:
sandblasting the surface of the oxide film layer away from the surface-to-be-covered of the body; and
cleaning the surface of the oxide film layer away from the surface-to-be-covered of the body.

19. The method for preparing reaction chamber component according to claim 16, wherein covering the surface of the oxide film layer away from the surface-to-be-covered of the body with the ceramic layer comprises:
preheating the oxide film layer;
selecting ceramic powder with a preset purity and a preset particle size, and spraying the ceramic powder to the surface of the oxide film layer away from the surface-to-be-covered of the body to form the ceramic layer; and
annealing the ceramic layer.

20. The method for preparing reaction chamber component according to claim 19, wherein: the preset purity is greater than 99.99%; and a value range of the preset particle size is 5 μm -10 μm.
